(19) United States
(12) Patent Application Publication
(10) Pub. No.: US 2007/0284084 A1
(43) Pub. Date: Dec. 13, 2007

(54) Radiator with buckle

(75) Inventor: Sheng-Huang Lin, Taipei (TW)

Correspondence Address: Asia Vital Components Co., Ltd., P.O. Box 1-195, YUNG HO, omitted

(73) Assignee: ASIA VITAL COMPONENTS CO., LTD., TAIPEI (TW)

(21) Appl. No.: 11/451,334

(22) Filed: Jun. 12, 2006

(51) Int. Cl. H01L 23/34; H05K 7/20

(52) U.S. Cl. 165/80.3; 165/104.33; 361/704; 257/719

(57) ABSTRACT

A radiator with buckle is disclosed. At least two buckling plates buckle to the radiator. The radiator comprises a plurality of fins. The fin has at least one hole for receiving the above buckling plate. The buckling plate has a main body, the two sides of the main body have at least one pressing portion that fit into holes of the radiator. The main body has a least one protrusion extending towards a direction opposite to the pressing portion from another side thereof to buckle to a corresponding buckle. The buckling plates are securely buckled to the radiator.

### BACKGROUND OF THE INVENTION

1. Field of invention

The present invention generally relates to a radiator, and more particularly to a radiator having a plurality of fins and a buckle.

2. Description of the Related Art

Conventional buckling element of the radiator comprises a main body having a beam. The beam comprises a groove that passes from an end to the other end, and comprises a leg axially connected to the two ends of the beam, wherein the distal end of the leg corresponds to a securing set and the thickness of the leg positioned in the groove is greater than the weight of the groove. The coordination of the leg and the groove of the main body enable the leg and the groove stay steady at any angle. The main body also comprises an operating element axially connected to the central portion of the beam of the main body, wherein the operating element is rotatable at an axis located between the horizontal and vertical positions.

Another conventional buckling element of a radiator comprises a base having a plurality of fins extending upwards and a space without any fins formed thereon, a connection element having a protrusion at a distal end thereof positioned below the radiator, and a buckling element comprising a main body with a pressing portion. The two distal ends of the main body comprise an extended first buckling portion and a second buckling portion with a handle. The handle of the second buckling portion comprises a bent portion formed at end portion of the main body. When an external force is applied on the handle of the buckling element, the pressing portion presses the space without any fins of the radiator and the buckling portion buckles to the protrusion of the connection element to substantially secure the radiator onto the connecting element.

Another conventional buckling element of a radiator comprises a radiator having a base and a plurality of fins formed thereon. The buckling element comprises at least one positioning element, two operating elements and two buckling elements. The positioning element is fixed to the radiator. Each of the operating elements has a pressing portion and an operating bent portion protruding from the pressing portion. The pressing portion is rotatably positioned on the positioning element, and the operating portion can rotate around the pressing portion and may be positioned upright and swing horizontally to position at a horizontal position. The pressing portion is bent and protruded to form a motor positioned at an angle with the operating portion. The two buckling elements are connected to the motor portion of the operating element.

The above conventional buckling elements have some common features, for instance, the buckling element and the radiator are separate elements, and the buckling element presses the radiator and buckles the radiator to the heating element only when the user uses the radiator. However, the radiator and the buckling element are not being used right after they are manufactured. The radiator and the buckling element are packaged and then transported to retail stores where they are sold to the user. Even after they are assembled, the buckling element may come loose during the transportation and may get lost. The radiator is not operable without the buckling element. Besides, the cost may be increased due to loss of the merchandize. Furthermore, the second conventional buckling element is horizontally positioned pressing the space without any fins formed thereon. Generally, a space is formed at the central hottest area of the radiator facing the air outlet of the fan. Thus, not only the air flow is affected but also the hottest area of the radiator may not provide the best heat exchange effect. Accordingly, the overall heat dissipation effect is not so effective. Besides, the third conventional radiator requires a positioning element, which would not only incur an extra work for assembly but also increases the overall cost.

Accordingly, how to overcome the above defects is an important issue for manufacturers in the field.

### SUMMARY OF THE INVENTION

Accordingly, in the view of the foregoing, instead of using an air duct formed by a conventional plastic injection process, the present invention proposes a radiator and buckling plates assembled together during the manufacturing process. Thus, the buckling plate will not be lost during packaging process or transportation, and the radiator and the buckling plates need not be assemble again before use.

According to another aspect of the present invention, the buckling plates are assembled on the two sides of the radiator. Thus, the airflow in the central heating region of the radiator will not be affected.

In accordance with the above objectives and other objectives, the present invention provides a radiator with buckling plates. The radiator with buckling plates comprises a radiator having a plurality of alternately positioned fins with gaps there-between. Each of the fins comprises a hole and at least two buckling plates. Each of the buckling plates comprises a main body having at least one pressing portion and at least one buckling element. The pressing portion extends towards a side from the two distal ends of the main body and is adopted for fitting into a corresponding hole of the fin of the radiator. The buckling element protrudes from a side opposite to the pressing portion.

### BRIEF DESCRIPTION OF THE DRAWING

For a more complete understanding of the present invention, reference will now be made to the following detailed description of preferred embodiments taken in conjunction with the following accompanying drawings.

FIG. 1 is an exploded view of a radiator according to an embodiment of the present invention.

FIG. 2 is a perspective view of a radiator according to an embodiment of the present invention.

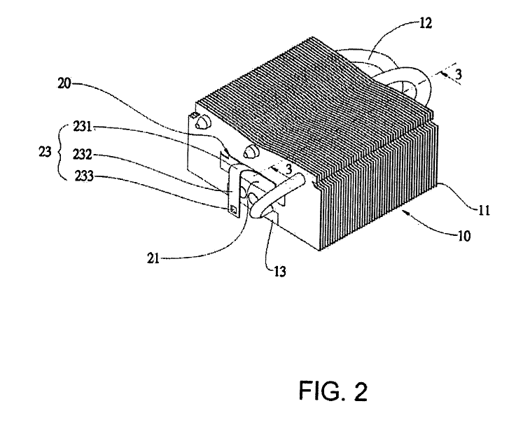

FIG. 3 is a cross sectional view taken along line 3-3 of FIG. 2.

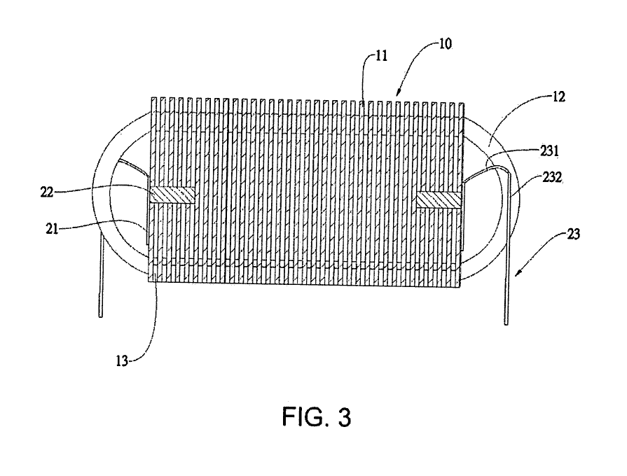

FIG. 4 is a view showing the radiator being assembled to the heating element of the components according to an embodiment of the present invention.

FIG. 5 is a side view showing the radiator buckled to a chassis according to an embodiment of the present invention.

### DETAIL DESCRIPTION OF THE INVENTION

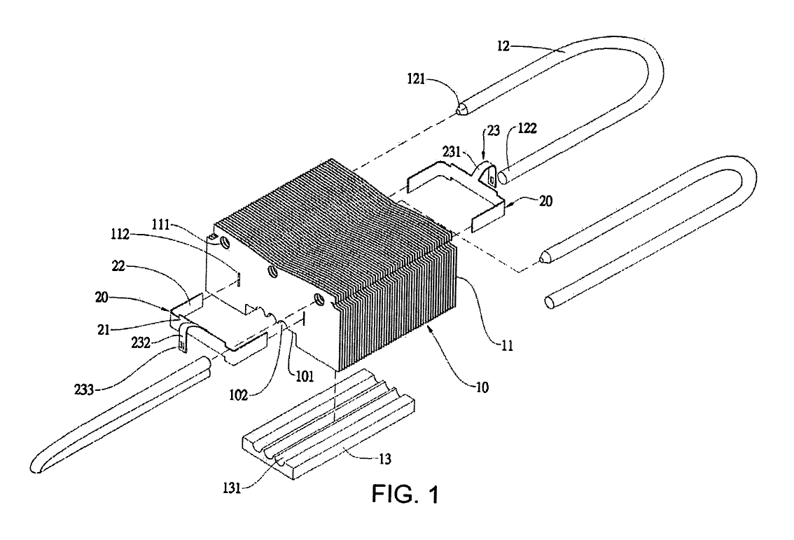

Referring to FIG. 1, 2 and 3, the present invention provides a radiator 10 and at least two buckling plates 20. The radiator 10 comprises a plurality of fins 11, at least one heat conductive tube 12 and at least one base 13.

The fins 11 are positioned in parallel with gaps between adjacent fins 11, and each fin 11 comprises at least one hole 111 on a surface near an upper end portion thereof and a groove at the lower end portion thereof. The groove forms the groove 101 of the radiator 10, and comprises a plurality of indentations 102 (three are shown in the Fig.). In other words, no hole is formed on the fins positioned near the central region.

The base 13 is assembled in the groove 101, and a side facing towards the fin 11 is closely attached to the fin 11, and the surface corresponding to indentations 102 has at least one groove 131.

The heat conductive tube 12 has a roughly U shape, an end 121 thereof penetrates through the hole 111 of the fins 11, and the other end 122 is connected to the base 13 and is positioning between the indentation 102 of the groove 101 and the groove 131 of the base 13.

Each of the two buckling plates have a main body 21. The main body 21 comprises a pressing portion 22 formed on two distal ends protruding towards a side thereof. Thus, the pressing portions 22 of the two buckling plates may be symmetrically formed and are inserted into the holes 112 formed the two opposite sides of the fin 11 of the radiator 10. The buckling plates 20 are positioned on two opposite sides of the fin 11 of the radiator 10. The two distal ends of the main body 21 comprise at least one buckling element 23 extending towards the opposite direction of the pressing portion 22. The buckling element 23 is preferably positioned on the middle portion of the main body 21. The buckling element 23 has a resilient arm 231 that extend upwards. A buckling arm 232 is formed extending from the resilient arm 231 that bent downwards. The buckling arm 232 comprises a buckling portion 233 formed at the lower end thereof. The buckling portion 233 may be a buckling hole or a simple hole (not shown).

The pressing portion 22 and the buckling element 23 may be integrally formed with the main body 21 or may be formed as separate elements jointed to the main body 21. The pressing portion 22 and the hole 112 can be jointed together using a suitable adhesive glue.

Furthermore, the fin 11 of the radiator 10 and the base 13 are comprised of different thermal conductive materials, for example, the fin 11 may be comprised of aluminum and the base 13 may be comprised of copper, or both fin 11 of the radiator 10 and the base 13 may be comprised of the same thermal conductive material, for example, aluminum.

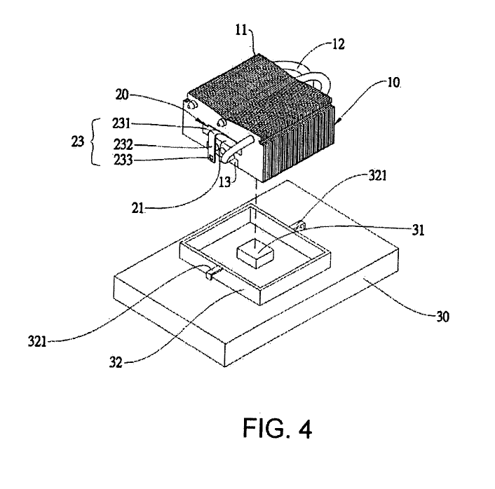

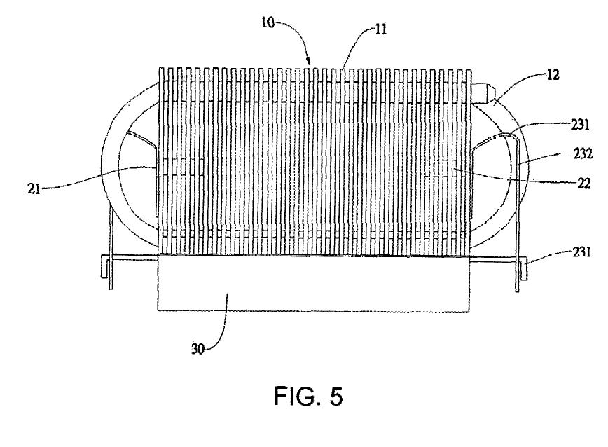

Referring to FIGS. 4 and 5, a heating element 31, for example CPU, on the circuit board 30 and a chassis 32 are shown, wherein the chassis 32 surrounds the heating element 31. The chassis 32 comprises two protrusions 321 formed on two sides thereof to correspondingly position the radiator 10 on the heat element 31 and the chassis 32. The buckling portion 233 of the buckling plates 20 respectively correspond to the two protrusions 321 formed the two sides of the chassis 32. Thus, the base 13 comprises another side attached to the heating element 31. Furthermore, the resilient arm 231 of the buckling element 23 may be pressed to buckle the buckling portion 233 of the buckling arm 232 to the protrusion 321 to securely position the radiator 10 onto the heating element 31.

The buckling plates 20 of the present invention comprises the pressing portion 22 that directly fit on two sides of the radiator 10 to secure the buckling plates 20 to the radiator 10 and this may be accomplished during the manufacturing process. Thus, the buckling plates 20 remain secured and will not be lost during packaging or transportation. Furthermore, no positioning element (RM adaptor) is required to secure to the radiator 10. Accordingly, the assembly time may be substantially reduced. The radiator 10 can directly buckle to the heating element 31 with the buckling plates secured on two sides of the radiator 10. Thus, the airflow of the central heating area of the radiator 10 is not adversely affected and the heat dissipation effect may be effectively promoted.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What is claimed is:

1. A radiator with buckle, comprising:
a radiator, comprising a plurality of fins, wherein each fin comprises at least a hole; and
a least two buckling plates, each comprising a main body having at least one pressing portion extending from a side thereof, and at least a buckling element extending from a side of said main body, wherein said buckling element extends towards an opposite direction of said pressing portion.

2. The radiator with buckle according to claim 1, wherein said buckling element is positioned on a middle portion of the main body and comprises a resilient arm extending upwards from a protruded end thereof and a buckling arm formed along said resilient arm.

3. The radiator with buckle according to claim 2, wherein said lower end of said buckling arm comprises a buckling portion corresponding to said protrusion.

4. The radiator with buckle according to claim 3, wherein said buckling portion comprises a buckling hole.

5. The radiator with buckle according to claim 4, wherein said buckling portion comprises a hook.

6. The radiator with buckle according to claim 1, wherein said buckling element is integrally formed with said main body.

7. The radiator with buckle according to claim 1, wherein said buckling element and said main body are formed as separate elements.

8. The radiator with buckle according to claim 1, wherein said pressing portion and said hole are adhered using an adhesive glue.

9. The radiator with buckle according to claim 1, wherein said pressing portion and said main body are integrally formed.

10. The radiator with buckle according to claim 1, wherein said pressing portion and said main body are formed as separate elements.

11. The radiator with buckle according to claim 1, wherein said radiator comprises a base having a side attached to said plurality of fins.

12. The radiator with buckle according to claim 11, wherein said radiator comprises at least one thermal conductive tube having an end penetrating through said holes of said fins and another end connected to said base.

13. The radiator with buckle according to claim 11, wherein said fin and said base are comprised of different thermal conductive materials.

14. The radiator with buckle according to claim 11, wherein said fin and said base are comprised of the same thermal conductive material.
